(19) United States
(12) Patent Application Publication
(10) Pub. No.: US 2008/0159833 A1
(43) Pub. Date: Jul. 3, 2008

(54) Printed circuit board transferring apparatus for chip mounter and printed circuit board transferring method using the same

(75) Inventors: Je-pil Lee, Gwangju-si (KR); Seong-ku Kim, Bucheon-si (KR)

Correspondence Address: DRINKER BIDDLE & REATH LLP;ATTN: PATENT DOCKET DEPT., 191 N. WACKER DRIVE, SUITE 3700, CHICAGO, IL, 60606, US

(73) Assignee: Samsung Techwin Co., Ltd., Changwon-city (KR)

(21) Appl. No.: 11/820,899

(22) Filed: Jun. 21, 2007

(30) Foreign Application Priority Data
Dec. 28, 2006 (KR) 10-2006-0136881

(51) Int. Cl. H01L 21/677

(52) U.S. Cl. 414/217.1

(57) ABSTRACT

Provided are a printed circuit board (PCB) transferring apparatus for a chip mounter, and a PCB transferring method using the PCB transferring apparatus. The PCB transferring apparatus includes: a base; first and second work lanes configured on the base to be parallel with each other for transferring and supporting PCBs; and a transferring unit configured in between the first and second work lanes for transferring wider PCBs.

### CROSS-REFERENCE TO RELATED PATENT APPLICATION

This application claims the benefit of Korean Patent Application No. 10-2006-0136881, filed on Dec. 28, 2006, in the Korean Intellectual Property Office, the disclosure of which is incorporated herein in its entirety by reference.

### BACKGROUND OF THE INVENTION

1. Field of the Invention

The present invention relates generally to printed circuit boards (PCBs). More particularly, the present invention relates to an apparatus and method for transferring PCBs to a chip mounter.

2. Description of the Related Art

In general, conveyer apparatuses are used in surface mount technology (SMT) related equipment such as chip mounters or screen printers. For example, a printed circuit board (PCB) substrate may be transferred by a conveyer to and from a chip mounter, which includes mounting heads for mounting various types of chips (e.g., IC chips) or the like on the PCB. Although conveyer apparatuses may be manufactured in various forms, generally such apparatuses transfer PCBs in a work lane using parallel belts. The belt is supported and moved by a pulley that rotates in response to a motor so as to transfer the PCB. A conveyer may include additional belts to provide additional work lanes, thus improving work efficiency of SMT equipment. A conveyer that is provided with such a dual work lane configuration may be adjustable according to a width of a PCB.

FIGS. 1 and 2 are plan views schematically illustrating a conventional chip mounter 10. Referring to FIGS. 1 and 2, the chip mounter 10 has a dual lane configuration and includes: two lanes 23 and 24 which are arranged parallel and adjacent to each other; a plurality of chip feeders 20; a front mounting head 21; and a back mounting head 22. The single lanes 23 and 24 respectively include first and second fixed rails 11 and 12, first and second movable rails 13 and 14, transfer belts 15, pulleys 17, and transfer belt driving motors 16. PCBs (indicated in FIG. 1 by reference P) carried into the single lanes 23 and 24 are transferred to mounting positions, and then chips are mounted on the transferred PCBs P by the mounting heads 21 and 22, for example, with the PCBs stopped. The first and second movable rails 13 and 14 may be moved in a direction that is generally perpendicular to a direction along which the PCBs P advance. That is, the PCBs P advance along an axis defined by a length of the lanes 23, 24 and/or the rails 11, 12, 13, 14, whereas the movable rails 13, 14 may be moved toward each other or away from each other along another axis that is generally perpendicular to the lanes 23, 24 and/or the rails 11, 12, 13, 14. Thus, the single lanes 23 and 24 may be adjusted by moving the first and second movable rails 13 and 14 according to widths of the PCBs P so that the chip mounter 10 may simultaneously mount chips on the PCBs P, which may have the same or different widths.

As can be appreciated, if the width of each of the PCBs P is greater than a distance t₁ (FIG. 1) defined between the first fixed rail 11 and the first movable rail 13 (or the distance between the second fixed rail 12 and the second movable rail 14), the PCBs P may not be simultaneously transferred. Instead, when one PCB P has a width that is greater than distance t₁, the first and second movable rails 13 and 14 may be moved toward the second fixed rail 12 as shown in FIG. 2 to widen a space between the first fixed rail 11 and the first movable rail 14 so as to transfer a PCB P₂ having a wide width and mount a chip on the PCB P₂.

However, as shown in FIG. 2, when the movable rails 13, 14 are adjusted to accommodate the wide width PCB P₂, the PCB P₂ is offset toward one of the chip feeders 20 so that the PCB P₂ is not positioned in a center of the chip mounter 10 and is instead adjacent the first fixed rail 11. Thus, movement distances of the front and back mounting heads 21 and 22 to the PCB P₂ are different from each other. Thus, work efficiency is reduced. In other words, while the front mounting 30 head 21 mounts a chip on a PCB P₂, the back mounting head 22 is fed with a chip from the chip feeder 20. While the front mounting head 21 mounts the chip on the PCB P₂ and then moves to the chip feeder 20, the back mounting head 22 moves to mount a chip on the PCB P₂. While the back mounting head 22 mounts the chip on the PCB P₂, the front mounting head 21 is fed with a chip from the chip feeder 20. However, if the PCB P₂ is inclined toward the first fixed rail 11, the movement distance of the back mounting head 22 becomes longer than that of the front mounting head 21. Thus, movement times of the back and front mounting heads 21 and 22 are different from each other. As a result, work efficiency is reduced. In other words, while the back mounting head 22 moves to mount the chip on the PCB P₂, the front mounting head 21 does not move but waits. Thus, a total time required for mounting chips on the offset PCB P₂ is delayed.

### SUMMARY OF THE INVENTION

The present invention provides a printed circuit board (PCB) transferring apparatus for a chip mounter and a PCB transferring method using the PCB transferring apparatus.

According to an aspect of the present invention, there is provided a PCB transferring apparatus for a chip mounter, including: a base; first and second work lanes disposed on the base to be parallel with each other for substantially simultaneously transferring and supporting PCBs having widths that are less than or equal to a predetermined width; and a transferring unit in between the first and second work lanes, the transferring unit being configured to transfer PCBs having widths that are greater than the predetermined width.

According to another aspect of the present invention, there is provided a PCB transferring method for a chip mounter including first and second work lanes that transfer and support PCBs having widths that are less than or equal to a predetermined width and a transferring unit in between the first and second work lanes, the transferring unit being configured to transfer PCBs having widths that are greater than the predetermined width, the method including: providing a PCB on which a chip is to be mounted; determining a width of the PCB; if the width of the PCB is greater than the predetermined width, adjusting a distance in between the first and second work lanes, to provide a transferring unit therebetween, to the determined width of the PCB; and transferring the PCB using adjacent inner portions of the first and second work lanes.

### BRIEF DESCRIPTION OF THE DRAWINGS

FIGS. 1 and 2 are schematic plan views of a conventional dual-lane chip mounter showing lane width adjustment thereof;

FIG. 3 is a perspective view of an example printed circuit board (PCB) transferring apparatus for a chip mounter according to an aspect of the present invention;

FIG. 4A is a side view of the PCB transferring apparatus of FIG. 3;

FIG. 4B is an enlarged view of portion A of FIG. 4A; and

FIGS. 5A and 5B are schematic plan views of the PCB transferring apparatus of FIG. 3 showing lane width adjustment thereof.

### DETAILED DESCRIPTION OF THE EMBODIMENTS

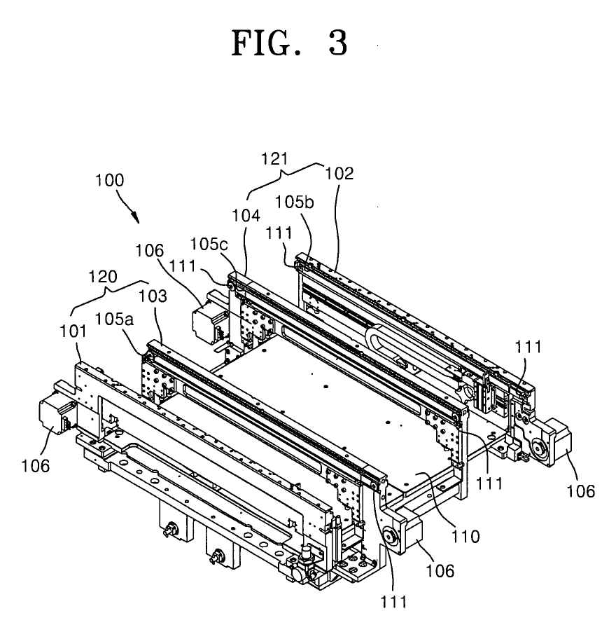

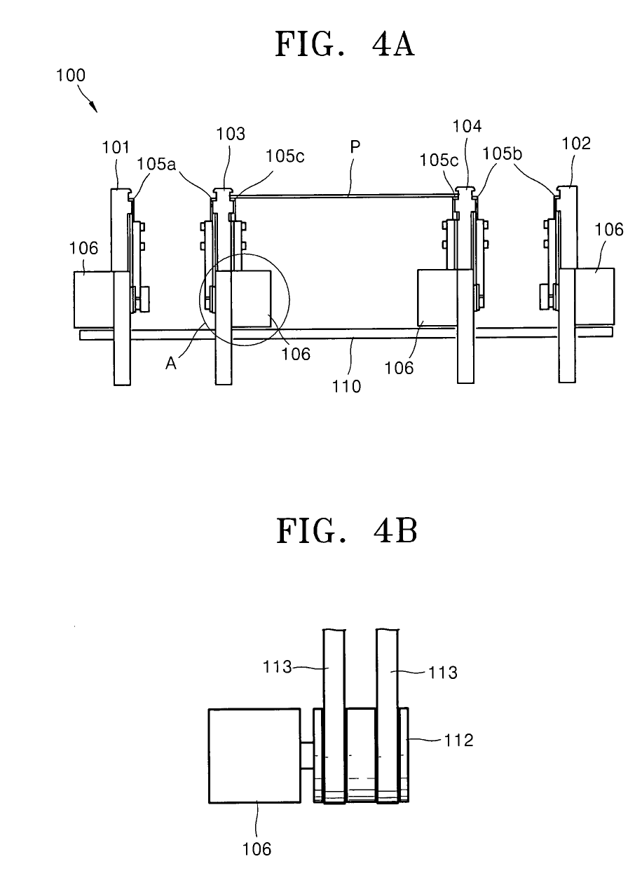

FIG. 3 is a perspective view of an example printed circuit board (PCB) transferring apparatus for a chip mounter according to an aspect of the present invention, and FIG. 4A is a side view of the PCB transferring apparatus of FIG. 3.

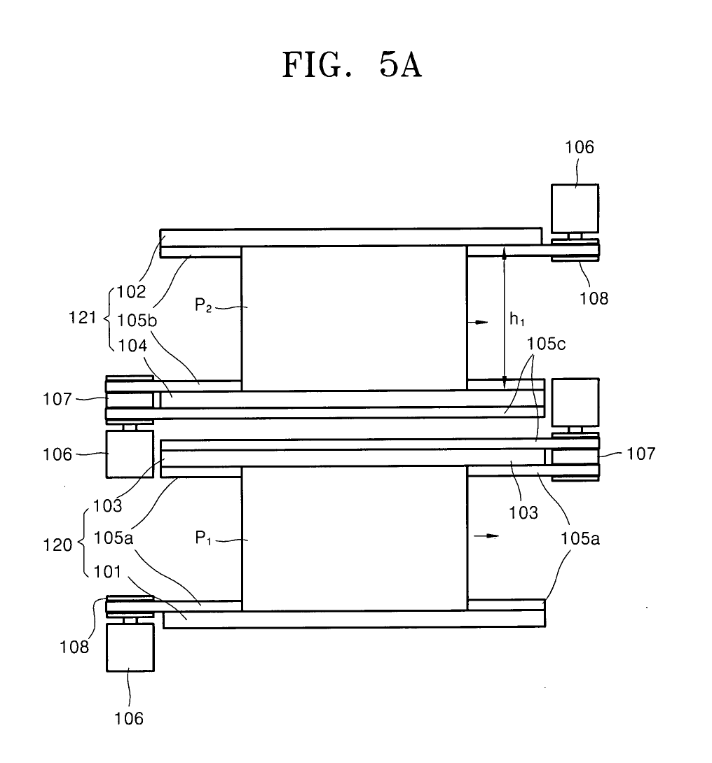

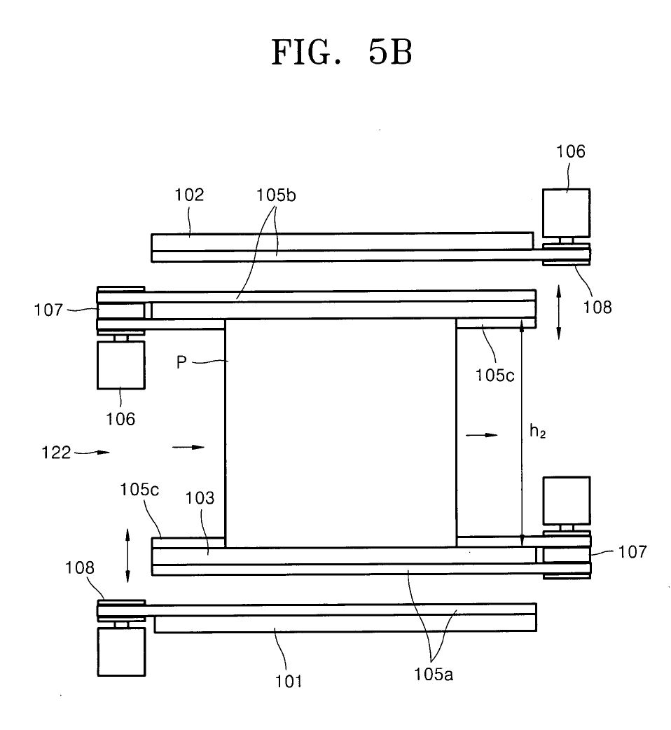

Referring to FIGS. 3 and 4A, a PCB transferring apparatus 100 includes a base 110, a first work lane 120, a second work lane 121, and a transferring unit in between the first and second work lanes 120, 121 that provides a third work lane 122 (FIG. 5B).

The first and second work lanes 120 and 121 are configured on the base 110 to be parallel with and adjacent to each other for supporting and transferring PCBs.

The first work lane 120 includes a first fixed rail 101, a first movable rail 103, first transfer belts 105a, and belt driving motors 106.

The first fixed rail 101 is fixed proximate to a first edge of the base 110, and the first movable rail 103 is configured on an inside portion of the base 110 to be parallel with the first fixed rail 101. The first movable rail 103 is installed to move toward and away from the first fixed rail 101 along an axis that is generally perpendicular to a length of the first fixed rail 101, i.e., the axis is generally perpendicular to a direction along which a PCB P is transferred. The PCB transferring apparatus 100 may further include a first rail moving unit (not shown) which moves the first movable rail 103 toward or away from the first fixed rail 101. The first rail moving unit may be combined with or separate from the first movable rail 103. In one example, the first rail moving unit may include a first transferring screw (not shown) and a first rail moving motor (not shown). The first transferring screw may be coupled with the first movable rail 103, for example, extending through a threaded aperture so that when the first rail moving motor rotates its shaft, the first transferring screw is turned to move the rail 103. As should be appreciated, the present apparatus 100 is not limited to the foregoing-described first rail moving unit. Indeed, the PCB transferring apparatus 100 may include any device, actuator, linkage, etc. known in the art for moving one object toward and away from another object.

The first transfer belts 105a and pulleys 111 are installed on facing sides of the first movable rail 103 and the first fixed rail 101. That is, as best illustrated in FIG. 4A, one first transfer belt 105a is configured on an inside or inward-facing portion of the first fixed rail 101 whereas another first transfer belt 105a is configured on an outside or outward-facing portion of the first movable rail 103. As shown in FIG. 3, the pulleys 111 are installed on both ends of each of the first fixed rail 101 and the first movable rail 103 so as to rotate and more the first transfer belts 105a. The first transfer belts 105a are installed on outer surfaces of the pulleys 111 and thus travel along the rotations of the pulleys 111. The pulleys 111 may be controlled to be rotated by driving of the belt driving motors 106 installed on sides of the first fixed rail 101 and the first movable rail 103.

As further shown in FIGS. 3 and 4A, the second work lane 121 includes a second fixed rail 102, a second movable rail 104, second transfer belts 105b, and belt driving motors 106.

The second fixed rail 102 is fixed to a second edge of the base 110 that is opposite to the first edge where the first fixed rail 101 is configured. The second movable rail 104 is configured between the first movable rail 103 and the second fixed rail 102 to be generally parallel with the rails 101, 102, 103. The second movable rail 104 is installed to move toward and away from the second fixed rail 102 along an axis that is generally perpendicular to a length of the second fixed rail 102, i.e., the axis is generally perpendicular to a direction along which a PCB P is transferred. The PCB transferring apparatus 100 may further include a second movable rail moving unit (not shown) which moves the second movable rail 104 toward or away from the second fixed rail 102. The second rail moving unit may be combined with or separate from the second movable rail 104. In one example, the second rail moving unit may include a second transferring screw (not shown) and a second rail moving motor (not shown). The second transferring screw may be coupled with the second movable rail 104, for example, extending through a threaded aperture so that when the second rail moving motor rotates its shaft, the second transferring screw is turned to move the rail 104. As should be appreciated, the present apparatus 100 is not limited to the foregoing-described second rail moving unit. Indeed, the PCB transferring apparatus 100 may include any device, actuator, linkage, etc. known in the art for moving one object toward and away from another object.

The second transfer belts 105b and pulleys 111 are installed on facing sides of the second fixed rail 102 and the second movable rail 104. That is, as best illustrated in FIG. 4A, one second transfer belt 105b is configured on an inside or inward-facing portion of the second fixed rail 102 whereas another second transfer belt 105b is configured on an outside or outward-facing portion of the second movable rail 104. As shown in FIG. 3, the pulleys 111 are installed on both ends of each of the second fixed rail 102 and the second movable rail 104 so as to rotate and move the second transfer belts 105b. The second transfer belts 105b are installed on outer surfaces of the pulleys 111 and thus travel along the rotations of the pulleys 111. The pulleys 111 may be controlled to be rotated by driving of the belt driving motors 106 installed on sides of the second fixed rail 102 and the second movable rail 104.

Third transfer belts 105c and pulleys 111 are installed on inner or inward-facing sides of the first movable rail 103 and the second movable rail 104. That is, as best illustrated in FIG. 4A, one third transfer belt 105c is configured on an inside or inward-facing portion of the first movable rail 103 whereas another third transfer belt 105c is configured on an inside or inward-facing portion of the second movable rail 104. The pulleys 111 are installed on both ends of each of the first and second movable rails 103 and 104 so as to rotate and move the third transfer belts 105c. The third transfer belts 105c are installed on outer surfaces of the pulleys 111 and thus travel along the rotations of the pulleys 111. The pulleys 111 may be controlled to be rotated by driving of the belt driving motors 106 installed on sides of the first and second movable rails 103 and 104.

A PCB may be transferred along the first work lane 120 by the first transfer belts 105a of the first fixed and movable rails 101 and 103, and thus a chip may be mounted on the PCB by a first mounting head (not shown) that corresponds and/or cooperates with the first work lane 120. Also, another PCB may be transferred along the second work lane 121 by the second transfer belts 105b of the second fixed and movable rails 102 and 104, and thus a chip may be mounted on the another PCB by a second mounting head (not shown) that corresponds and/or cooperates with the second work lane 121. As can be appreciated, the first and second movable rails 103, 104 may both be moved inward (i.e., toward each other) so that the first and second work lanes 121 can be adjusted to the same maximum predetermined width.

Third transfer belts 105c and pulleys 111 are installed on facing sides of the first and second movable rails 103 and 104. Thus, the first and second movable rails 103, 104 define a third work lane 122 (FIG. 5B) on which a PCB may be transferred to mount a chip on the PCB. Thus, if a PCB has a width that is greater than the maximum predetermined width of the first and second work lanes 120, 121, the third work lane 122 may be employed. The pulleys 111, the first transfer belts 105a, and the third transfer belts 105c installed on both sides of the first movable rail 103 may be driven by different motors. However, as shown in FIG. 4B multiple belts 113 (e.g., the first and third transfer belts 105a and 105c of rail 103) may be driven by the same belt driving motor 106. Similarly, the pulleys 111, the second transfer belts 105b, and the third transfer belts 105c may be driven by different motors. However, as can be appreciated from FIG. 4B, the second and third transfer belts 105b and 105c of rail 104 may be driven by the same belt driving motor 106.

FIG. 4B is an enlarged view of portion A of FIG. 4A including the belt driving motor 106. Referring to FIG. 4B, the belt driving motor 106 includes a pulley 112 driving two belts 113. The two belts 113 may be installed on both sides of the pulley 112. The two belts 113 are respectively connected to the pulleys 111 installed on both sides of the first movable rail 103 (or the second movable rail 104). The first and third transfer belts 105a and 105c (or the second and third transfer belts 105b and 105c) are installed on the pulleys 111. Thus, the first and third transfer belts 105a and 105c installed on both sides of the first movable rail 103 (or the second movable rail 104) are driven by the belt driving motor 106. In FIG. 4B, the two belts 113 are installed on the pulley 112 but the belt driving configuration of the present apparatus is not limited as such. However, each of two pulleys may be combined with one belt. As described above, the belt driving motor 106 drives the first and third transfer belts 105a and 105b (or the second and third transfer belts 105b and 105c) installed on both sides of the first movable rail 103 (or the second movable rail 104).

The operation of the. PCB transferring apparatus 100 will now be described in detail with reference to FIGS. 5A and 5B.

FIGS. 5A and 5B are schematic plan views of the PCB transferring apparatus 100 of FIG. 3. In other words, FIG. 5A illustrates PCBs P₁ and P₂ which are simultaneously transferred, and FIG. 5B illustrates a PCB P which is transferred.

The PCB transferring apparatus 100 including the first and second work lanes 120, 121 can mount chips on PCBs having various widths because the first and second movable rails 103 and 104 are adjustably movable toward and away from each other. Thus, a first distance between the first movable and fixed rails 103 and 101 (i.e., a width of the first work lane 120) and a second distance between the second movable and fixed rails 104 and 102 (i.e., a width of the second work lane 121) may be adjusted according to widths of the PCBs being transferred on the lanes 120, 121. Referring to FIG. 5A, the PCB P₁ is transferred in the first work lane 120, i.e., between the first fixed and movable rails 101 and 103, and the PCB P₂ is transferred in the second work lane 121, i.e., between the second fixed and movable rails 102 and 104. Thus, as shown in FIG. 5A, two PCBs having predetermined widths (which may be the same or different) may be substantially simultaneously transferred. If a width of each of the PCBs P₁ and P₂ is smaller than a predetermined maximum width h₁ of each of the first and second work lanes 120 and 121 (i.e., when the first and second movable rails 103, 104 are configured at their inward-most orientations), then mounting chips on the two PCBS as shown in FIG. 5A may be substantially simultaneously performed. As described above, two PCBs can be substantially simultaneously transferred to maximize efficiency of a work speed.

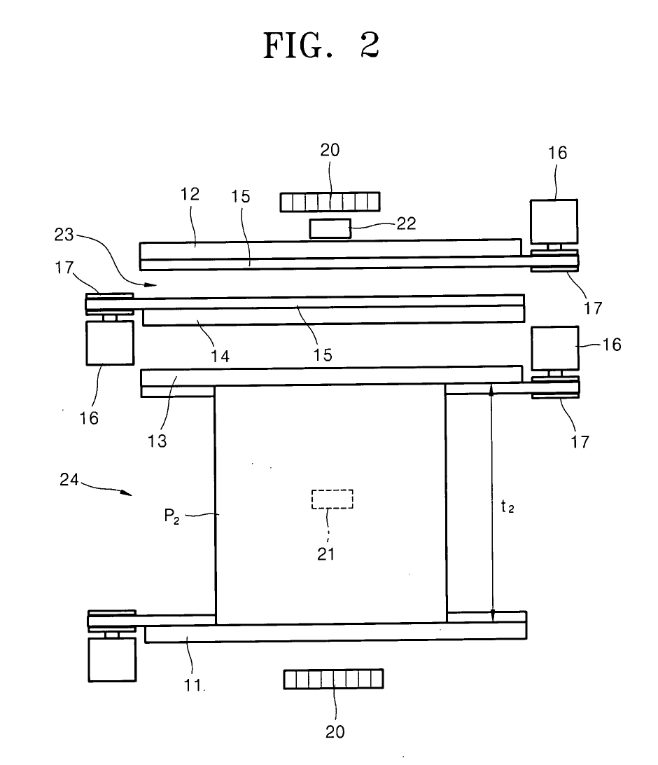

As shown in FIG. 5B, a width h₂ of the PCB P is greater than the maximum width h₁ of each of the first and second work lanes 120 and 121. Because the PCB width h₂ is greater than h₁, two PCBs may not be transferred side by side in adjacent work lanes 120, 121 for mounting chips substantially simultaneously on the two PCBs. In such instances when the PCB has a width that is larger than a predetermined maximum width ha of each of the first and second work lanes 120 and 121, it can be appreciated that the first and second movable rails 103, 104, which include the third transfer belts 105c on the inward facing sides of the first and second movable rails 103 and 104, may be adjustably moved outward (i.e., toward the respective first and second fixed rails 101, 102) to provide a transferring unit that accommodates the PCB in between the first and second work lanes 120, 121, without causing the PCB to be offset from the chip feeder (as shown in FIG. 2).

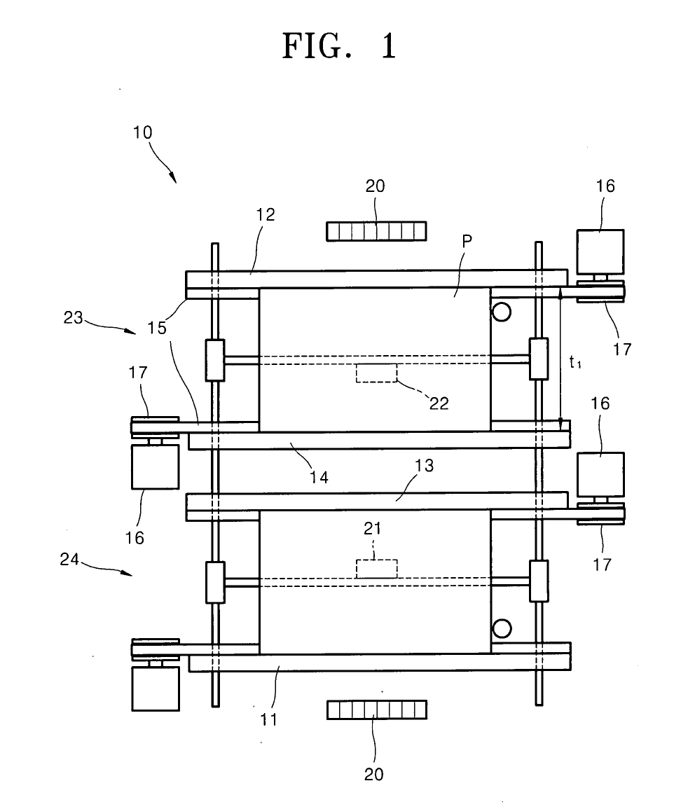

PCB transferring apparatus 100 includes the transferring unit defined by the third transfer belts 105c on the inward facing sides of the first and second movable rails 103 and 104 so as to provide the third work lane 122. Thus, the space between the first and second movable rails 103 and 104, i.e., the third work lane 122, can be used as the work area. In other words, the first movable rail 103 moves toward the first fixed rail 101, and the second movable rail 104 moves toward the second fixed rail 102 so as to configure a wide work area between the first and second movable rails 103 and 104. Thus, a PCB having a wide width can be transferred to mount a chip on the PCB. The space between the first and second movable rails 103 and 104 can be used as the work area to position a PCB in a center of a chip mounter. If a chip is mounted on a PCB using front and back mounting heads (not shown) of dual gantry equipment that move from front and back chip feeders (e.g., 20, FIGS. 1 and 2), the front and back mounting heads move the same distance to mount the chip on the PCB. Thus, standby times of the front and back mounting heads can be reduced. As a result, work efficiency can be improved by about 10% to 15%.

A PCB transferring method for a chip mounter according to an aspect of the present invention will now be described in detail with reference to FIGS. 5A and 5B.

A chip mounter includes a PCB transferring apparatus with first and second work lanes 120, 121 and a transferring unit in between the first and second work lanes 120, 121. At least one PCB on which a chip is to be mounted is provided, and then widths of the at least one PCB are determined (e.g., with an optical system or the like). If the widths the PCBs are smaller than the predetermined maximum width of the first or second work lane 120 or 121, the first movable rail 103 and/or the second movable rail 104 are respectively moved toward the first and second fixed rails 101 and 102. Thus, the width of each of the first and second work lanes 120 and 121 is adjusted to the width of the PCBs P₁ and P₂, and the PCBs P₁ and P₂ are transferred in the first and second work lanes 120 and 121.

However, if a width of at least one of the PCBs is greater than the maximum predetermined width of the first or second work lane 120 or 121, the transferring unit is selected to transfer that at least one PCB. In selecting the transferring unit, a third work lane 122 is provided in between the first and second work lanes 120 and 121. In other words, the first movable rail 103 is moved toward the first fixed rail 101, and the second movable rail 104 is moved toward the second fixed rail 102 to form the third work lane 122 and transfer the PCB in the third work lane 122. Pulleys installed on inner facing sides of the first and second movable rails 103 and 104 so as to rotate, and the third transfer belts 105c are installed to be traveled by the pulleys. Thus, the PCB can be transferred on the first and second movable rails 103 and 104.

As can be appreciated, in the present PCB transferring apparatus and method for a chip mounter, transfer belts can be installed on both sides of each of first and second movable rails. Thus, a space between the first and second movable rails can be configured as a work area. As a result, if a width of a PCB is small, two PCBs can be substantially simultaneously transferred. Therefore, speed efficiency can be improved. If the width of the PCB is great, the PCB can be positioned in a center of the chip mounter to improve work efficiency.

While the present invention has been particularly shown and described with reference to example embodiments thereof, it will be understood that various changes in form and details may be made therein without departing from the spirit and scope of the present invention as defined by the following claims. For example, although an example apparatus and method have been shown and described as including pulleys and belts for transferring PCBs, the present apparatus and method for transferring PCBs may alternatively include other devices (e.g., linear or rotational actuators such as electric or hydraulic motors, etc.) and linkages (e.g., belts, cables, ropes, linear or rotational gears, etc.) known in the conveyor art for transferring objects.

What is claimed is:

1. A PCB transferring apparatus for a chip mounter, comprising:
a base;
a first work lane configured on the base for transferring and supporting PCBs having widths less than a predetermined value;
a second work lane generally parallel with the first work lane, the second work lane configured on the base for transferring and supporting PCBs having widths less than the predetermined value; and
a transferring unit for transferring and supporting PCBs having widths greater than the predetermined value, the transferring unit configured in between and generally parallel with the first and second work lanes.

2. The PCB transferring apparatus of claim 1, wherein the first work lane comprises:
a first fixed rail configured along a first edge of the base;
a first actuator coupled with the first fixed rail;
a first movable rail generally parallel with the first fixed rail, the first movable rail configured on an inner portion of the base and being adjustably movable toward and away from the first fixed rail; and
a second actuator coupled with the first movable rail.

3. The PCB transferring apparatus of claim 2 further comprising a rail moving member connected to the first movable rail for translating the first movable rail toward and away from the first fixed rail.

4. The PCB transferring apparatus of claim 3 wherein the rail moving member comprises:
a motor with a rotating shaft; and
a screw member including one end connected with the rotating shaft and another end connected with the first movable rail.

5. The PCB transferring apparatus of claim 2, wherein the second work lane comprises:
a second fixed rail configured along a second edge of the base opposite to the first edge of the base;
a third actuator coupled with the second fixed rail;
a second movable rail generally parallel with the second fixed rail, the second movable rail configured on an inner portion of the base and being adjustably movable toward and away from the second fixed rail; and
a fourth actuator coupled with the second movable rail.

6. The PCB transferring apparatus of claim 5 further comprising a rail moving member connected to the second movable rail for translating the second movable rail toward and away from the second fixed rail.

7. The PCB transferring apparatus of claim 6 wherein the rail moving member comprises:
a motor with a rotating shaft; and
a screw member including one end connected with the rotating shaft and another end connected with the second movable rail.

8. The PCB transferring apparatus of claim 5 wherein at least one of the first actuator and the second actuator comprises:
first pulleys installed on inner sides of the respective first fixed and movable rails;
a first transfer belt extending around the first pulleys; and
a first motor coupled with the first pulleys for driving the first transfer belt.

9. The PCB transferring apparatus of claim 8 wherein at least one of the third actuator and the fourth actuator comprises:
second pulleys installed on inner sides of the respective second fixed and movable rails;
a second transfer belt extending around the second pulleys, and
a second motor coupled with the second pulleys for driving the second transfer belt.

10. The PCB transferring apparatus of claim 9 wherein the transferring unit is defined by the first movable rail and the second movable rail.

11. The PCB transferring apparatus of claim 10 wherein the transferring unit comprises:
third pulleys installed on an inward-facing portion of the first movable rail and the second movable rail, and
a third transfer belt extending around the third pulleys.

12. The PCB transferring apparatus of claim 11 wherein the first transfer belt and the third transfer belt of the first movable rail are driven by the first motor of the second actuator.

13. The PCB transferring apparatus of claim 12 wherein the second transfer belt and the third transfer belt of the second movable rail are driven by the second motor of the fourth actuator.

14. A PCB transferring method for a chip mounter including first and second work lanes that transfer and support PCBs having widths smaller than a predetermined value and a transferring unit configured in between the first and second work lanes that transfers and supports PCBs having widths greater than the predetermined value, the method comprising:
providing a PCB on which a chip is to be mounted;
determining a width of the PCB;
comparing the width from the determining step with the predetermined value;
if the width is greater than the predetermined value, configuring a third work lane in between the first and second work lanes to substantially correspond with the width; and
conveying the PCB along the third work lane in between the first and second work lanes.

15. The method of claim 14, wherein if the width is less than the predetermined value, adjusting a work lane width of at least one of the first and second work lanes to substantially correspond with the width.

16. The method of claim 15, wherein the configuring step comprises adjusting a distance in between the first and second work lanes.

17. The method of claim 16 wherein the adjusting step comprises:
moving an inner rail of the first work lane in an outward direction; and
moving an inner rail of the second work lane in an outward direction.

18. The method of claim 14, wherein the conveying step comprises activating at least one actuator of the first and second work lanes.

19. A PCB transferring apparatus for a chip mounter, comprising:
a base;
a first fixed rail including a first actuator, the first fixed rail configured along a first edge of the base
a first movable rail including a second actuator on a first side facing the first fixed rail and a third actuator on a second side, the first movable rail configured generally parallel with the first fixed rail on an inner portion of the base and being adjustably movable toward and away from the first fixed rail, wherein the first fixed rail and the first movable rail define a first work lane;
a second fixed rail including a fourth actuator, the second fixed rail configured along a second edge of the base opposite to the first edge of the base; and
a second movable rail including a fifth actuator on a first side facing the second fixed rail and a sixth actuator on a second side, the second movable rail configured generally parallel with the second fixed rail on an inner portion of the base and being adjustably movable toward and away from the second fixed rail, wherein the second fixed rail and the second movable rail define a second work lane;
and wherein the first movable rail and the second movable rail define a third work lane.

20. The PCB transferring apparatus of claim 19 further comprising:
a first rail moving member connected to the first movable rail for translating the first movable rail toward and away from the first fixed rail; and
a second rail moving member connected to the second movable rail for translating the second movable rail toward and away from the second fixed rail,
wherein at least one of the first and second rail moving member includes a motor with a rotating shaft, and a screw member including one end connected with the rotating shaft and another end connected with the respective first or second movable rail,
and wherein at least one of the actuators includes pulleys, a transfer belt extending around the pulleys, and a motor coupled with the pulleys for driving the transfer belt.
